(19) United States
(12) Patent Application Publication
(10) Pub. No.: US 2026/0293410 A1
(43) Pub. Date: Sep. 24, 2026

(54) LED Packaging Structure, Multi-color LED Matrix, and Control Method Thereof

(71) Applicants: HUAYUAN SEMICONDUCTOR (SHENZHEN) LIMITED COMPANY, Shenzhen (CN); Huayuan Semiconductor (Tianjin) Limited Company, Tianjin (CN)

(72) Inventors: Junyue Sun, Shenzhen (CN); Haiming Yu, Shenzhen (CN); Yufeng Zou, Shenzhen (CN); Ao Chen, Shenzhen (CN)

(21) Appl. No.: 19/557,063

(22) Filed: Mar. 4, 2026

(30) Foreign Application Priority Data
Mar. 18, 2025 (CN) 202510319044.9

(51) Int. Cl. H10H 29/85; H10H 29/24

(52) U.S. Cl. CPC H10H 29/857; H10H 29/24

(57) ABSTRACT

The present application provides an LED packaging structure, a multi-color LED matrix, and a control method thereof. In the LED packaging structure, a driver chip is used to drive a first multi-color light-emitting unit located within the same package body and a second multi-color light-emitting unit located outside that package body. This allows a single driver chip to drive multiple multi-color light-emitting units, thereby reducing the design cost. Moreover, because the driver chip and the first multi-color light-emitting unit are located within the same package body, the mounting cost for applying the LED packaging structure can also be reduced. Additionally, the LED packaging structure includes two active power supply pin sets and a plurality of passive power supply pin sets, making routing more convenient during PCB layout design and reducing the problem of trace crossing between the LED modules and power lines, which enables single-sided layout and single-layer routing.

### CROSS REFERENCE TO RELATED APPLICATIONS

The present application claims the benefit of Chinese Patent Application No. 202510319044.9 filed on Mar. 18, 2025, the contents of which are incorporated herein by reference in their entirety.

### TECHNICAL FIELD

The present application relates to the field of LED devices, and more particularly, to an LED packaging structure, a multi-color LED matrix, and a control method thereof.

### BACKGROUND

RGB pixel chips are typically composed of three independent LED chips, corresponding to the colors of red, green, and blue, respectively. These chips are integrated through precision packaging technology to form a complete pixel unit used for image display or illumination.

However, as the number of RGB pixel chips increases, the number of driver chips required to drive these RGB pixel chips also increases, which consequently leads to an increase in cost. Furthermore, an RGB pixel chip only has three power supply pins corresponding to the three LED chips. Since the power supply voltages applied to these three power supply pins differ from one another, problems of cross-routing (or "crossing traces") arise when the RGB pixel chips are connected to the power supply and when the individual RGB pixel chips are interconnected with one another.

### SUMMARY OF THE INVENTION

The present application provides an LED packaging structure, a multi-color LED matrix, and a control method thereof to save costs and achieve single-layer routing on a PCB.

According to the technical solutions of the present application, an LED packaging structure is provided, including:

an active LED module, the active LED module including a first multi-color light-emitting unit, a driver chip, and a plurality of driving signal output pin sets, the driver chip being connected to the first multi-color light-emitting unit, the first multi-color light-emitting unit and the driver chip being located within a same package body, and the driving signal output pin sets being configured to output driving signals;

two active power supply pin sets, both of the two active power supply pin sets being coupled to the active LED module;

at least one first-type passive LED module, the first-type passive LED module including a second multi-color light-emitting unit and a driving signal input pin set, the driving signal input pin set being connected to a corresponding one of the driving signal output pin sets, and the driver chip being configured to drive the first multi-color light-emitting unit and the second multi-color light-emitting unit to emit light of a same color at a same time, the color being one of a plurality of colors; and

at least two passive power supply pin sets, each two of the passive power supply pin sets being coupled to a corresponding first-type passive LED module, and a number of the passive power supply pin sets being twice a number of the first-type passive LED modules; the active power supply pin sets are connected to the passive power supply pin sets adjacent thereto, the remaining passive power supply pin sets are connected to the passive power supply pin sets adjacent thereto, and two connected passive power supply pin sets are respectively coupled to different first-type passive LED modules.

Optionally, both of the two active power supply pin sets are connected to the active LED module, and each two of the passive power supply pin sets are connected to a corresponding one of the first-type passive LED modules.

Optionally, the first multi-color light-emitting unit and the second multi-color light-emitting unit each include a first pixel structure, a second pixel structure, and a third pixel structure, and light colors emitted by the first pixel structure, the second pixel structure, and the third pixel structure are different;

the driver chip is respectively connected to the first pixel structure, the second pixel structure, and the third pixel structure in the first multi-color light-emitting unit;

each driving signal output pin set includes a first driving signal output pin, a second driving signal output pin, and a third driving signal output pin, and each driving signal input pin set includes a first driving signal input pin, a second driving signal input pin, and a third driving signal input pin; in one driving signal output pin set and a driving signal input pin set corresponding thereto, the first driving signal output pin is connected to the first driving signal input pin, the second driving signal output pin is connected to the second driving signal input pin, and the third driving signal output pin is connected to the third driving signal input pin.

Optionally, the LED packaging structure further includes:

a plurality of second-type passive LED modules connected in series, where in a first one of the second-type passive LED modules and the active LED module, the first pixel structure of one is correspondingly connected to the first pixel structure of the other, the second pixel structure of one is correspondingly connected to the second pixel structure of the other, and the third pixel structure of one is correspondingly connected to the third pixel structure of the other; a last one of the second-type passive LED modules is connected to two active power supply pin sets, and in any two adjacent second-type passive LED modules, the first pixel structure of one is correspondingly connected to the first pixel structure of the other, the second pixel structure of one is correspondingly connected to the second pixel structure of the other, and the third pixel structure of one is correspondingly connected to the third pixel structure of the other;

a plurality of third-type passive LED module sets, each including a plurality of third-type passive LED modules connected in series, and a number of the third-type passive LED modules in each set is the same as a number of the second-type passive LED modules; in each third-type passive LED module set, a first one of the third-type passive LED modules corresponds to one first-type passive LED module, and in the first one of the third-type passive LED modules and the first-type passive LED module corresponding thereto, the first pixel structure of one is correspondingly connected to the first pixel structure of the other, the second pixel structure of one is correspondingly connected to the second pixel structure of the other, and the third pixel structure of one is correspondingly connected to the third pixel structure of the other; a last one of the third-type passive LED modules is connected to two passive power supply pin sets, and in any two adjacent third-type passive LED modules, the first pixel structure of one is correspondingly connected to the first pixel structure of the other, the second pixel structure of one is correspondingly connected to the second pixel structure of the other, and the third pixel structure of one is correspondingly connected to the third pixel structure of the other.

Optionally, the active power supply pin set includes a first active power supply pin, a second active power supply pin, and a third active power supply pin, and the passive power supply pin set includes a first passive power supply pin, a second passive power supply pin, and a third passive power supply pin. In this configuration, the first active power supply pin and the first passive power supply pin are connected to a same power supply voltage to supply power to the first pixel structure; the second active power supply pin and the second passive power supply pin are connected to a same power supply voltage to supply power to the second pixel structure; and the third active power supply pin and the third passive power supply pin are connected to a same power supply voltage to supply power to the third pixel structure. The first active power supply pin, the second active power supply pin, and the third active power supply pin are connected to power supply voltages of different magnitudes.

Optionally, the active power supply pin set includes a first active power supply pin and a fourth active power supply pin, and the passive power supply pin sets each include a first passive power supply pin and a fourth passive power supply pin. In this case, the first active power supply pin and the first passive power supply pin are connected to a same power supply voltage to supply power to the first pixel structure; the fourth active power supply pin and the fourth passive power supply pin are connected to a same power supply voltage to supply power to the second pixel structure and the third pixel structure; and the first active power supply pin and the fourth active power supply pin are connected to power supply voltages of different magnitudes.

Optionally, the driver chip is used to output a corresponding driving signal according to a control instruction; alternatively, the driver chip includes a random signal module used to control the driver chip to randomly output a driving signal;

the driving signal is used to control a lighting order of the LED packaging structure within a frame of time. The driving signal includes a first driving signal, a second driving signal, and a third driving signal, which are respectively used to drive the first pixel structure, the second pixel structure, and the third pixel structure in the first multi-color light-emitting unit and the second multi-color light-emitting unit. The driving signal output pin set includes a first driving signal output pin, a second driving signal output pin, and a third driving signal output pin, these pins being respectively used to output the first driving signal, the second driving signal, and the third driving signal, and the driving signal is connected to the first pixel structure, the second pixel structure, and the third pixel structure in the first multi-color light-emitting unit.

According to the technical solutions of the present application, a multi-color LED matrix is also provided, including:

a lamp board; and

a plurality of the above-mentioned LED packaging structures, the LED packaging structures being distributed in an array on the lamp board. In this matrix, a plurality of the active LED modules are connected in series through a data input pin and a data output pin; namely, in any two adjacent active LED modules, the data output pin of one is connected to the data input pin of the other.

According to the technical solutions of the present application, a control method for a multi-color LED matrix is further provided for controlling the above-mentioned multi-color LED matrix.

Optionally, a number of the LED packaging structures is at least two, and the control method for a multi-color LED matrix includes: at a same time, light emitted by at least one of the LED packaging structures is one color of the plurality of colors, and light emitted by at least one of the LED packaging structures is another color of the plurality of colors.

Compared with the prior art, the technical solutions of the present application have the following beneficial effects:

In the LED packaging structure, multi-color LED matrix, and control method thereof provided by the technical solutions of the present application, the driver chip is used to drive the first multi-color light-emitting unit within the same package body as the driver chip, as well as the second multi-color light-emitting unit not within the same package body as the driver chip. This allows a single driver chip to drive multiple multi-color light-emitting units, which reduces the design cost of applying the LED packaging structure. Moreover, since the driver chip and the first multi-color light-emitting unit are located within the same package body, the mounting cost of applying the LED packaging structure can also be reduced. In addition, the LED packaging structure includes two active power supply pin sets and a plurality of passive power supply pin sets. The active power supply pin set is connected to a passive power supply pin set adjacent thereto, and the remaining passive power supply pin sets are connected to adjacent passive power supply pin sets coupled to different first-type passive LED modules. This makes routing more convenient during PCB layout design and reduces the problem of trace crossing between the LED modules and power lines, thereby enabling single-sided layout and single-layer routing.

### DESCRIPTION OF THE DRAWINGS

FIG. 1 is a first schematic structural diagram of an LED packaging structure provided by an embodiment of the present application.

FIG. 2 is a second schematic structural diagram of an LED packaging structure provided by an embodiment of the present application.

FIG. 3 is a third schematic structural diagram of an LED packaging structure provided by an embodiment of the present application.

FIG. 4 is a first schematic structural diagram of an active LED module provided by an embodiment of the present application.

FIG. 5 is a second schematic structural diagram of an active LED module provided by an embodiment of the present application.

FIG. 6 is a first schematic structural diagram of a multi-color light-emitting unit provided by an embodiment of the present application.

FIG. 7 is a second schematic structural diagram of a multi-color light-emitting unit provided by an embodiment of the present application.

FIG. 8 is a schematic structural diagram of a multi-color LED matrix provided by an embodiment of the present application.

FIG. 9 is a voltage timing diagram of driving signals of two LED packaging structures in a multi-color LED matrix provided by an embodiment of the present application.

### REFERENCE NUMERALS

1 – LED packaging structure;
101 – First multi-color light-emitting unit;
102 – Driver chip;
103 – Second multi-color light-emitting unit;
104 – First pixel structure;
105 – Second pixel structure;
106 – Third pixel structure;
VC – Control instruction;
DI – Data input pin;
DO – Data output pin;
V1 – Active power supply pin set;
V2 – Passive power supply pin set;
V3 – Driving signal output pin set;
V4 – Driving signal input pin set;
V11 – First active power supply pin;
V12 – Second active power supply pin;
V13 – Third active power supply pin;
V14 – Fourth active power supply pin;
V21 – First passive power supply pin;
V22 – Second passive power supply pin;
V23 – Third passive power supply pin;
V24 – Fourth passive power supply pin;
V31 – First driving signal output pin;
V32 – Second driving signal output pin;
V33 – Third driving signal output pin;
V41 – First driving signal input pin;
V42 – Second driving signal input pin;
V43 – Third driving signal input pin.

### DETAILED DESCRIPTION

As described in the Background, as the number of RGB pixel chips increases, the drive cost increases accordingly, and problems of cross-routing arise when the RGB pixel chips are connected to the power supply and interconnected with one another.

In view of this, the technical solutions of the present application creatively provide an LED packaging structure, including:

an active LED module, the active LED module including a first multi-color light-emitting unit, a driver chip, and a plurality of driving signal output pin sets, where the driver chip is connected to the first multi-color light-emitting unit, the first multi-color light-emitting unit and the driver chip are located within a same package body, and the driving signal output pin sets are used to output driving signals;

two active power supply pin sets, both of which are coupled to the active LED module;

at least one first-type passive LED module, the first-type passive LED module including a second multi-color light-emitting unit and a driving signal input pin set, where each driving signal input pin set is connected to a corresponding driving signal output pin set, and the driver chip is used to drive the first multi-color light-emitting unit and the second multi-color light-emitting unit to emit light of a same color at a same time, the color being one of a plurality of colors; and

at least two passive power supply pin sets, each two of the passive power supply pin sets being coupled to a corresponding first-type passive LED module, and the number of the passive power supply pin sets is twice the number of the first-type passive LED modules; the active power supply pin set is connected to a passive power supply pin set adjacent thereto, and the remaining passive power supply pin sets are connected to adjacent passive power supply pin sets, while two connected passive power supply pin sets are respectively coupled to different first-type passive LED modules.

Therefore, by using one driver chip to drive both the first multi-color light-emitting unit located within the same package body as the driver chip and the second multi-color light-emitting unit located outside the same package body, both the drive cost and the mounting cost for applying the LED packaging structure can be reduced. In addition, the LED packaging structure includes two active power supply pin sets and a plurality of passive power supply pin sets, making routing more convenient during PCB layout design and reducing the problem of trace crossing between the LED modules and power lines, which enables single-sided layout and single-layer routing.

The embodiments in the present application are described clearly and completely below with reference to the accompanying drawings. Obviously, the described embodiments are only some, but not all, of the embodiments of the present application. Based on the embodiments in the present application, all other embodiments obtained by a person of ordinary skill in the art without creative efforts fall within the scope of protection of the present application. The terms "first," "second," "third," and the like in the specification, the claims, and the drawings of the present application are used to distinguish similar objects and are not necessarily used to describe a specific order or sequence. It should be understood that data used in this manner are interchangeable under appropriate circumstances so that the embodiments of the present application described herein can be implemented in orders other than those illustrated or described herein. In addition, the terms "comprise," "have," and any variations thereof are intended to cover non-exclusive inclusion. For example, a process, method, system, product, or device including a series of steps or units is not necessarily limited to those steps or units clearly listed, but may include other steps or units not clearly listed or inherent to such process, method, product, or device.

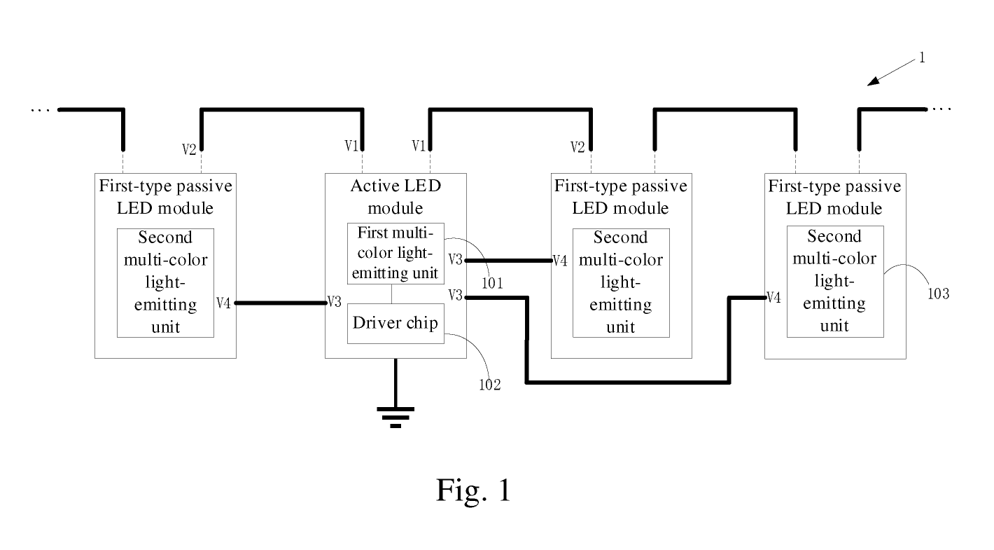

Please refer to FIG. 1. The LED packaging structure 1 includes: an active LED module, two active power supply pin sets V1, at least one first-type passive LED module, and at least two passive power supply pin sets V2.

The active LED module includes a first multi-color light-emitting unit 101, a driver chip 102, and a plurality of driving signal output pin sets. The driver chip 102 is connected to the first multi-color light-emitting unit 101, the first multi-color light-emitting unit 101 and the driver chip 102 are located within the same package body, and the driving signal output pin sets V3 are used to output driving signals.

The first-type passive LED module includes a second multi-color light-emitting unit 103 and a driving signal input pin set V4. Each driving signal input pin set V4 is connected to a corresponding driving signal output pin set V3. The driver chip 102 is used to drive the first multi-color light-emitting unit 101 and the second multi-color light-emitting unit 103 to emit light of a same color at a same time, and this color is one of a plurality of colors.

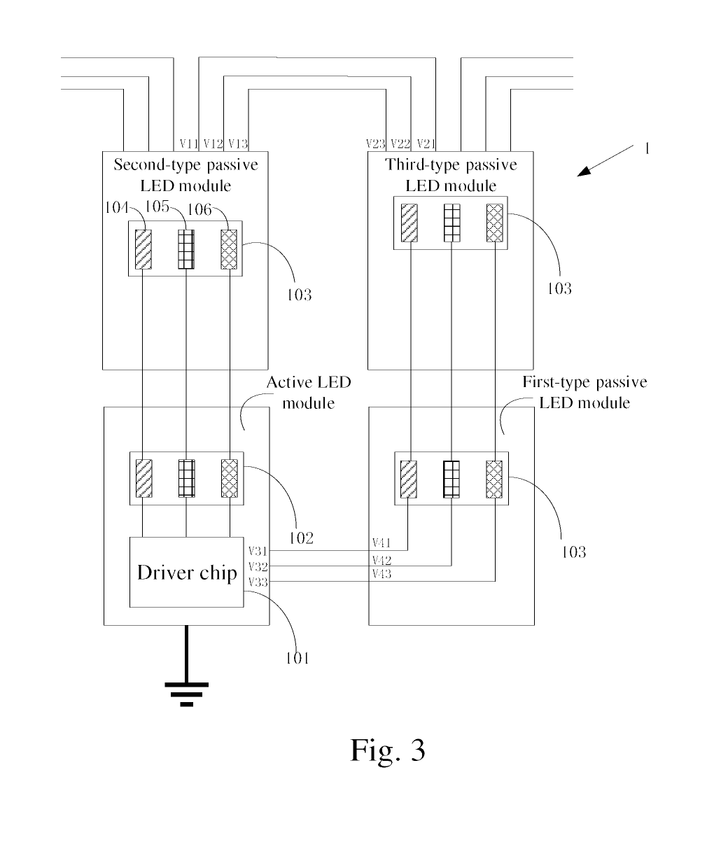

Please refer to FIG. 3. In this embodiment, the first multi-color light-emitting unit 101 and the second multi-color light-emitting unit 103 each include a first pixel structure 104, a second pixel structure 105, and a third pixel structure 106. Light colors emitted by the first pixel structure 104, the second pixel structure 105, and the third pixel structure 106 are different; for example, light emitted by the first pixel structure 104 is red light, light emitted by the second pixel structure 105 is green light, and light emitted by the third pixel structure 106 is blue light.

In this embodiment, please refer to FIG. 3. The driving signals include a first driving signal, a second driving signal, and a third driving signal. The driving signals are used to control a lighting order of the LED packaging structure 1 within a frame of time, and the first driving signal, the second driving signal, and the third driving signal are respectively used to drive the first pixel structure 104, the second pixel structure 105, and the third pixel structure 106 in the first multi-color light-emitting unit 101 and the second multi-color light-emitting unit 103.

The driver chip 102 is respectively connected to the first pixel structure 104, the second pixel structure 105, and the third pixel structure 106 in the first multi-color light-emitting unit 101. Specifically, the driver chip 102 is connected to the first pixel structure 104, the second pixel structure 105, and the third pixel structure 106 in the first multi-color light-emitting unit 101 so that the driver chip 102 can respectively send the first driving signal, the second driving signal, and the third driving signal to the first pixel structure 104, the second pixel structure 105, and the third pixel structure 106 in the first multi-color light-emitting unit 101. This allows the lighting order of the first pixel structure 104, the second pixel structure 105, and the third pixel structure 106 in the first multi-color light-emitting unit 101 within a frame of time to be controlled according to the received driving signals.

Each driving signal output pin set V3 in the active LED module includes a first driving signal output pin V31, a second driving signal output pin V32, and a third driving signal output pin V33. Each driving signal input pin set V4 includes a first driving signal input pin V41, a second driving signal input pin V42, and a third driving signal input pin V43. In one driving signal output pin set V3 and the driving signal input pin set V4 corresponding thereto, the first driving signal output pin V31 is connected to the first driving signal input pin V41, the second driving signal output pin V32 is connected to the second driving signal input pin V42, and the third driving signal output pin V33 is connected to the third driving signal input pin V43. Specifically, the first driving signal, the second driving signal, and the third driving signal are respectively output through the first driving signal output pin V31, the second driving signal output pin V32, and the third driving signal output pin V33 in each driving signal output pin set V3. These signals are then transmitted via the one-to-one correspondence connections between the pins V31, V32, V33 and the pins V41, V42, V43, so that the first driving signal input pin V41, the second driving signal input pin V42, and the third driving signal input pin V43 in each driving signal input pin set can correspondingly receive the first driving signal, the second driving signal, and the third driving signal. Consequently, the first pixel structure 104, the second pixel structure 105, and the third pixel structure 106 in the second multi-color light-emitting unit 103 of each first-type passive LED module can correspondingly receive the first driving signal, the second driving signal, and the third driving signal respectively through the first driving signal input pin V41, the second driving signal input pin V42, and the third driving signal input pin V43. This allows the lighting order of the first pixel structure 104, the second pixel structure 105, and the third pixel structure 106 in the second multi-color light-emitting unit 103 of each first-type passive LED module within a frame of time to be controlled based on the received driving signals.

Therefore, within the same frame of time, since the driving signals received by the first multi-color light-emitting unit 101 and each first-type passive LED module are the same, the lighting order of the first pixel structure 104, the second pixel structure 105, and the third pixel structure 106 in the first multi-color light-emitting unit 101 and the second multi-color light-emitting unit 103 of each first-type passive LED module is the same within the same frame of time. That is, at a same time, one LED packaging structure 1 emits light of one color, which is one of a plurality of colors.

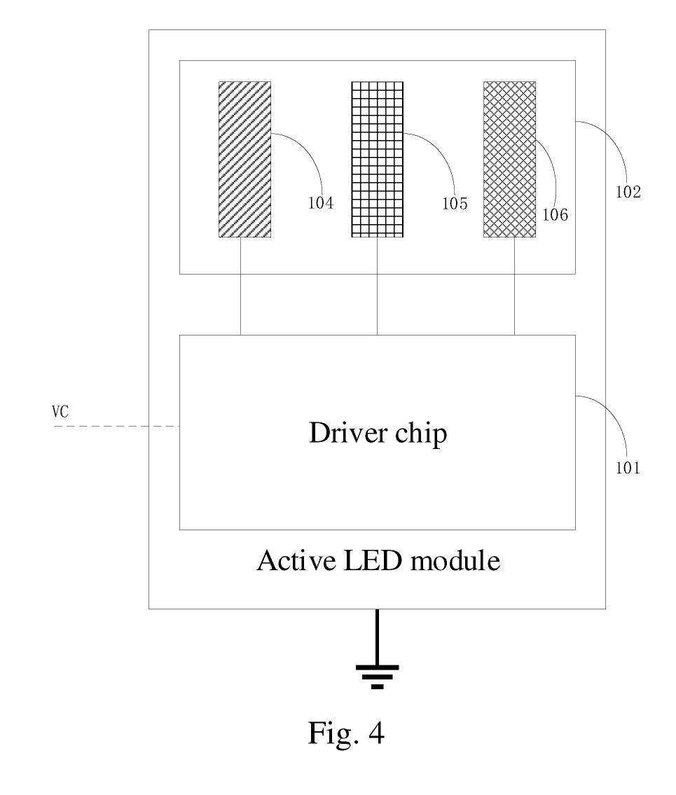

In an embodiment, referring to FIG. 4, the driver chip 102 is used to output a corresponding driving signal according to a control instruction VC. Specifically, the driver chip 102 can receive the control instruction VC frame by frame. In the control instruction VC, different data bits represent the lighting order of different pixel structures in the form of data frames, so that the driver chip 102 can control the lighting order of the LED packaging structure 1 within a frame of time according to the control instruction VC.

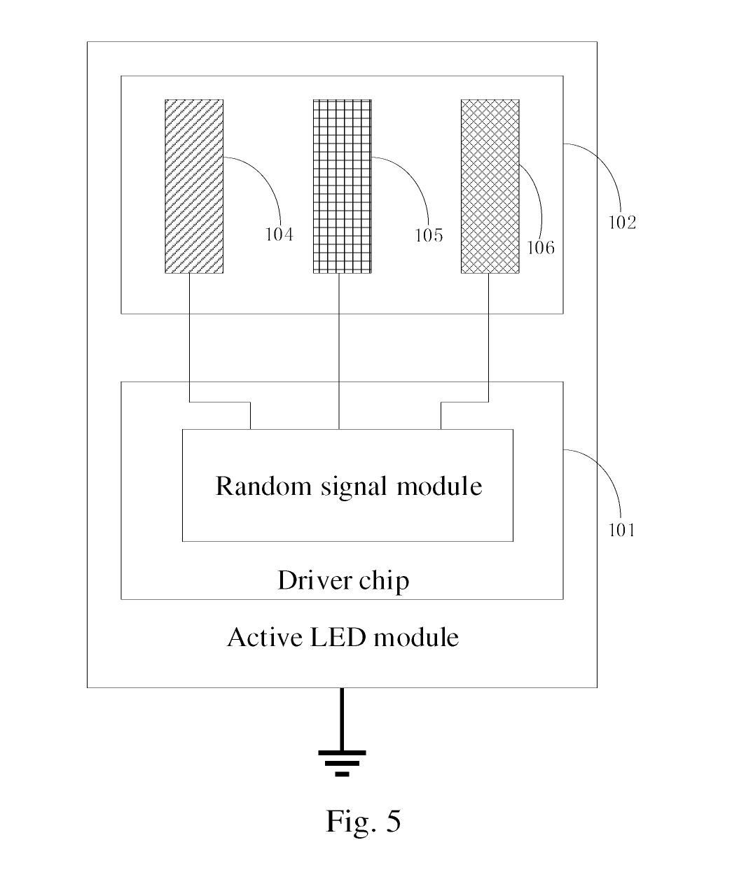

In another embodiment, referring to FIG. 5, the driver chip 102 includes a random signal module, which is used to control the driver chip 102 to randomly output driving signals.

Continuing to refer to FIG. 1, both of the two active power supply pin sets V1 are coupled to the active LED module.

Every two passive power supply pin sets V2 are coupled to a corresponding first-type passive LED module, and the number of the passive power supply pin sets V2 is twice the number of the first-type passive LED modules. An active power supply pin set V1 is connected to a passive power supply pin set V2 adjacent thereto, and the remaining passive power supply pin sets V2 are connected to passive power supply pin sets V2 adjacent thereto, while two connected passive power supply pin sets V2 are respectively coupled to different first-type passive LED modules. Therefore, all power supply pin sets are connected to power supply pin sets coupled to adjacent LED modules, making it possible to reduce the crossing of power lines during PCB design and layout, thereby achieving single-layer routing.

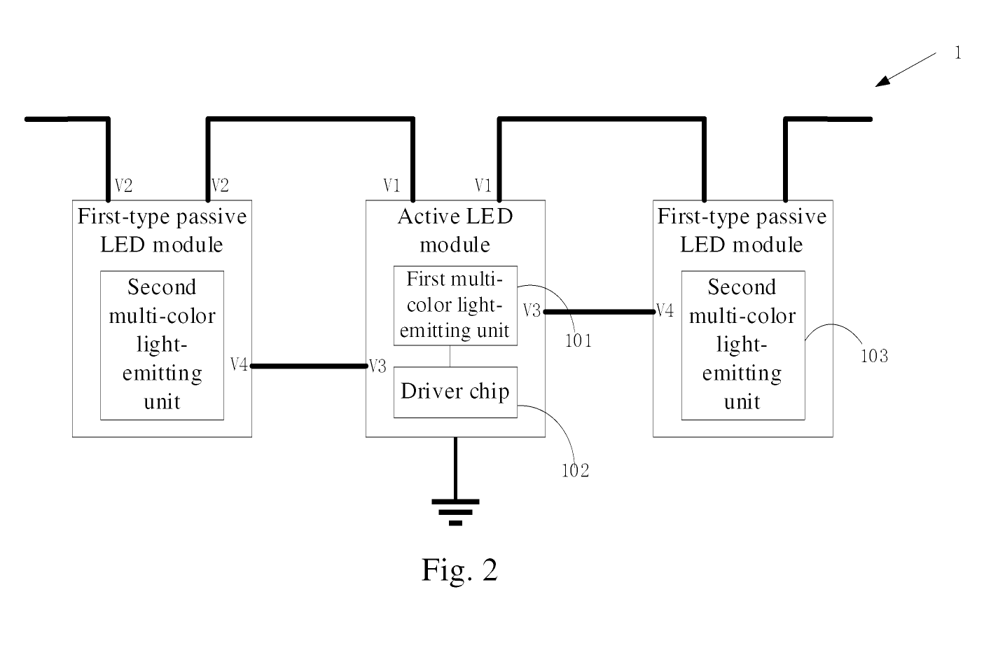

In an embodiment, referring to FIG. 2, both of the two active power supply pin sets V1 are connected to the active LED module, and each two of the passive power supply pin sets V2 are connected to a corresponding first-type passive LED module.

In another embodiment, referring to FIG. 3, the LED packaging structure 1 also includes a plurality of second-type passive LED modules connected in series and a plurality of third-type passive LED module sets.

Among the plurality of second-type passive LED modules connected in series, in a first one of the second-type passive LED modules and the active LED module, the first pixel structure 104 of one is correspondingly connected to the first pixel structure 104 of the other, the second pixel structure 105 of one is correspondingly connected to the second pixel structure 105 of the other, and the third pixel structure 106 of one is correspondingly connected to the third pixel structure 106 of the other. A last one of the second-type passive LED modules is connected to the two active power supply pin sets V1. Moreover, in any two adjacent second-type passive LED modules, the first pixel structure 104 of one is correspondingly connected to the first pixel structure 104 of the other, the second pixel structure 105 of one is correspondingly connected to the second pixel structure 105 of the other, and the third pixel structure 106 of one is correspondingly connected to the third pixel structure 106 of the other. Therefore, the first pixel structure 104 in the first multi-color light-emitting unit 101 is connected in series with the first pixel structure 104 in each second-type passive LED module, the second pixel structure 105 in the first multi-color light-emitting unit 101 is connected in series with the second pixel structure 105 in each second-type passive LED module, and the third pixel structure 106 in the first multi-color light-emitting unit 101 is connected in series with the third pixel structure 106 in each second-type passive LED module. This allows the driving signals received by the first multi-color light-emitting unit 101 to drive the active LED module and each second-type passive LED module, so that the lighting order of the first pixel structure 104, the second pixel structure 105, and the third pixel structure 106 in the active LED module and each second-type passive LED module within a same frame of time is the same.

Each third-type passive LED module set includes a plurality of third-type passive LED modules connected in series, and the number of third-type passive LED modules in each set is the same as the number of second-type passive LED modules. In each third-type passive LED module set, a first one of the third-type passive LED modules corresponds to one first-type passive LED module. In the first one of the third-type passive LED modules and the first-type passive LED module corresponding thereto, the first pixel structure 104 of one is correspondingly connected to the first pixel structure 104 of the other, the second pixel structure 105 of one is correspondingly connected to the second pixel structure 105 of the other, and the third pixel structure 106 of one is correspondingly connected to the third pixel structure 106 of the other. A last one of the third-type passive LED modules is connected to two passive power supply pin sets V2. Additionally, in any two adjacent third-type passive LED modules, the first pixel structure 104 of one is correspondingly connected to the first pixel structure 104 of the other, the second pixel structure 105 of one is correspondingly connected to the second pixel structure 105 of the other, and the third pixel structure 106 of one is correspondingly connected to the third pixel structure 106 of the other. Therefore, the first pixel structure 104 in the first-type passive LED module is connected in series with the first pixel structure 104 in each third-type passive LED module of the corresponding third-type passive LED module set. The second pixel structure 105 in the first-type passive LED module is connected in series with the second pixel structure 105 in each third-type passive LED module of the corresponding third-type passive LED module set, and the third pixel structure 106 in the first-type passive LED module is connected in series with the third pixel structure 106 in each third-type passive LED module of the corresponding third-type passive LED module set. This allows the driving signals received by the first-type passive LED module to drive the first-type passive LED module and each third-type passive LED module corresponding thereto, so that the lighting order of the first pixel structure 104, the second pixel structure 105, and the third pixel structure 106 in the first-type passive LED module and each third-type passive LED module corresponding thereto within a same frame of time is the same.

Therefore, within a same frame of time, since the driving signals received by the first multi-color light-emitting unit 101 and each first-type passive LED module are the same, the lighting order of the first pixel structure 104, the second pixel structure 105, and the third pixel structure 106 in the active LED module, the first-type passive LED module, the second-type passive LED module, and the third-type passive LED module within the same frame of time is the same. That is, at a same time, one LED packaging structure 1 emits light of one color, which is one of a plurality of colors.

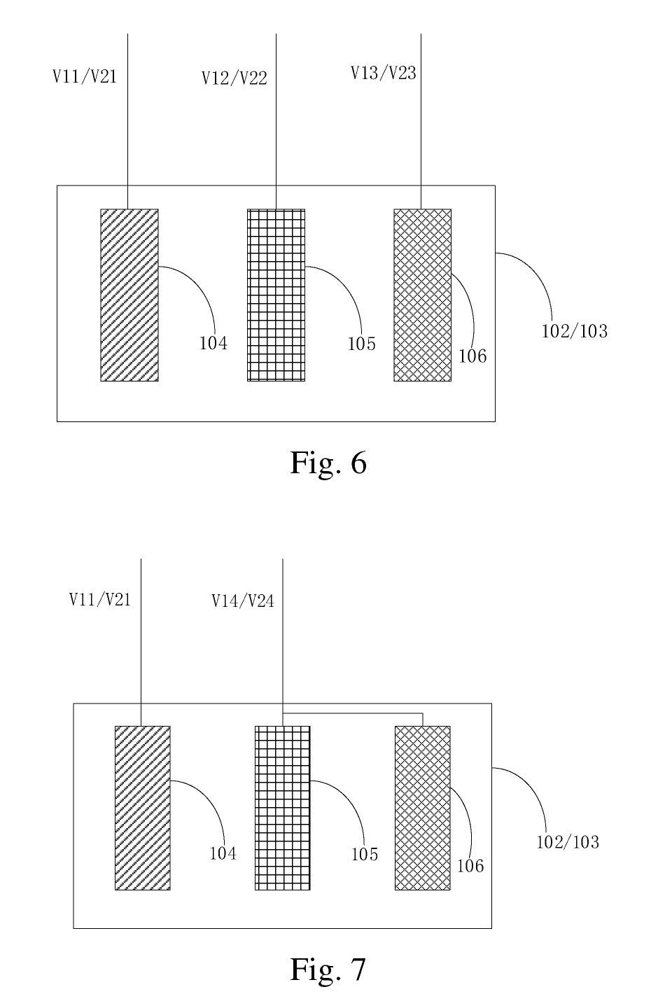

In an embodiment, referring to FIG. 6, the active power supply pin set V1 includes a first active power supply pin V11, a second active power supply pin V12, and a third active power supply pin V13, and the passive power supply pin set V2 includes a first passive power supply pin V21, a second passive power supply pin V22, and a third passive power supply pin V23. In this case, the first active power supply pin V11 and the first passive power supply pin V21 are connected to a same power supply voltage to supply power to the first pixel structure 104; the second active power supply pin V12 and the second passive power supply pin V22 are connected to a same power supply voltage to supply power to the second pixel structure 105; the third active power supply pin V13 and the third passive power supply pin V23 are connected to a same power supply voltage to supply power to the third pixel structure 106; and the first active power supply pin V11, the second active power supply pin V12, and the third active power supply pin V13 are connected to power supply voltages of different magnitudes. For example, light emitted by the first pixel structure 104 is red light, light emitted by the second pixel structure 105 is green light, and light emitted by the third pixel structure 106 is blue light; in this case, an operating voltage of the third pixel structure 106 is greater than an operating voltage of the second pixel structure 105, and the operating voltage of the second pixel structure 105 is greater than an operating voltage of the first pixel structure 104.

In another embodiment, referring to FIG. 7, the active power supply pin set V1 includes a first active power supply pin V11 and a fourth active power supply pin V14, and each passive power supply pin set V2 includes a first passive power supply pin V21 and a fourth passive power supply pin V24. In this case, the first active power supply pin V11 and the first passive power supply pin V21 are connected to a same power supply voltage to supply power to the first pixel structure 104; the fourth active power supply pin V14 and the fourth passive power supply pin V24 are connected to a same power supply voltage to supply power to the second pixel structure 105 and the third pixel structure 106; and the first active power supply pin V11 and the fourth active power supply pin V14 are connected to power supply voltages of different magnitudes. For example, light emitted by the first pixel structure 104 is red light, light emitted by the second pixel structure 105 is green light, and light emitted by the third pixel structure 106 is blue light; in this case, the operating voltages of the second pixel structure 105 and the third pixel structure 106 can be made the same by adjusting process parameters of the second pixel structure 105 and the third pixel structure 106.

In summary, in the LED packaging structure provided by the embodiments of the present application, the driver chip is used to drive the first multi-color light-emitting unit located within the same package body as the driver chip and the second multi-color light-emitting unit located outside that package body. This allows a single driver chip to drive multiple multi-color light-emitting units, thereby reducing the cost of applying the LED packaging structure. Moreover, because the driver chip and the first multi-color light-emitting unit are located within the same package body, the mounting cost for applying the LED packaging structure can also be reduced. In addition, the LED packaging structure includes two active power supply pin sets and a plurality of passive power supply pin sets. The active power supply pin set is connected to a passive power supply pin set adjacent thereto, and the remaining passive power supply pin sets are connected to adjacent passive power supply pin sets coupled to different first-type passive LED modules. This makes routing more convenient during PCB layout design and reduces the problem of trace crossing between the LED modules and power lines, thereby enabling single-sided layout and single-layer routing.

Embodiments of the present application also provide a multi-color LED matrix, including: a lamp board and a plurality of the LED packaging structures 1 in the above-mentioned embodiments.

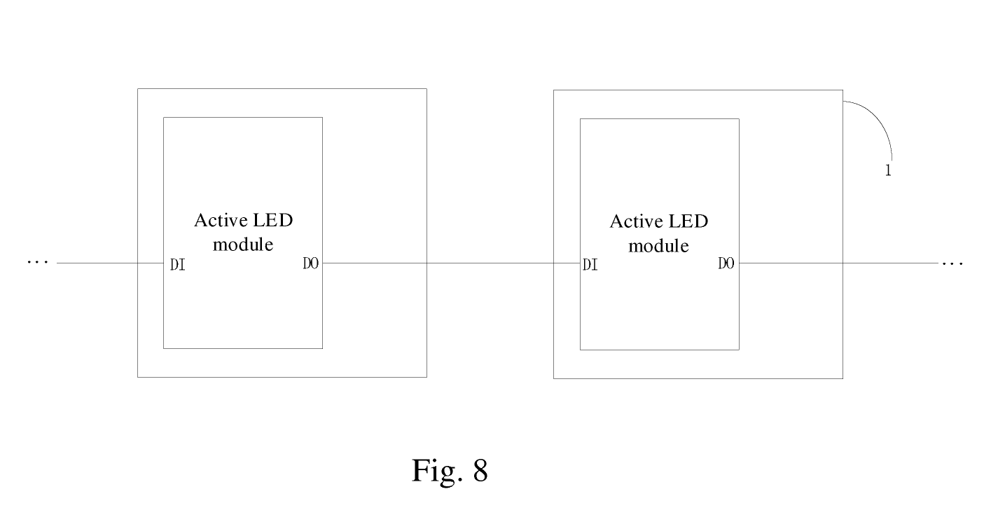

Referring to FIG. 8, the LED packaging structures 1 are distributed in an array on the lamp board, and a plurality of active LED modules are connected in series through data input pins DI and data output pins DO; specifically, in any two adjacent active LED modules, the data output pin DO of one is connected to the data input pin DI of the other. In this case, the data input pin DI can receive a signal carrying display information, and the signal carrying display information can be transmitted to the driver chip 102 through the data input pin DI, so that the driver chip 102 drives the LED packaging structure 1 according to the received signal carrying display information.

Correspondingly, embodiments of the present application also provide a control method for controlling the multi-color LED matrix in the above-mentioned embodiments.

In this embodiment, the number of the LED packaging structures 1 is at least two, and the control method for a multi-color LED matrix includes: at a same time, light emitted by at least one LED packaging structure 1 is one color of a plurality of colors, and light emitted by at least one LED packaging structure 1 is another color of the plurality of colors.

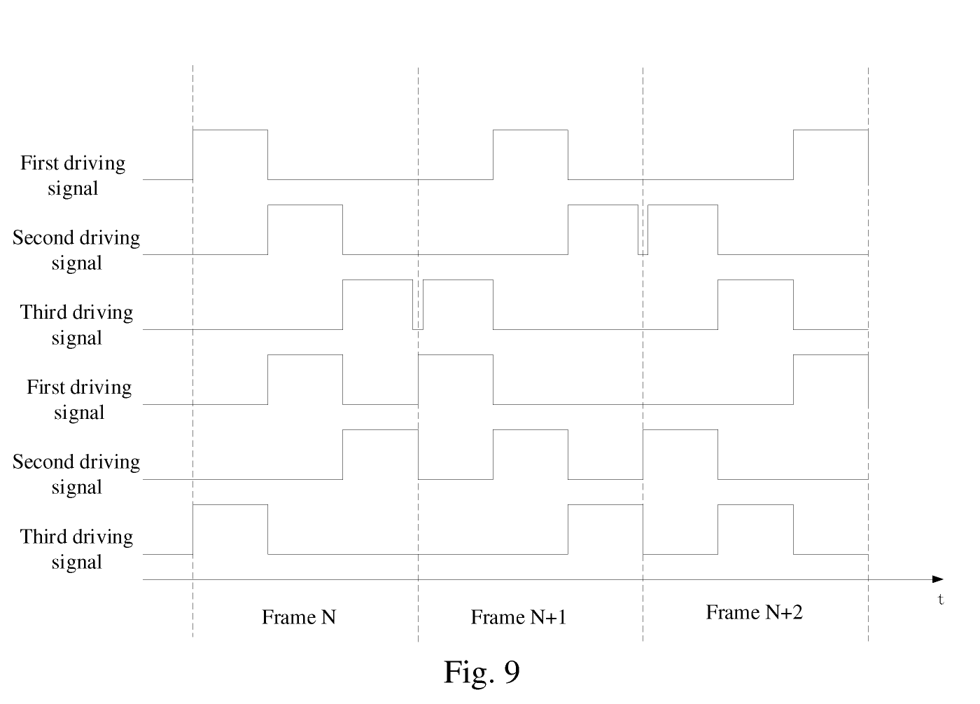

In a specific embodiment, referring to FIG. 9, FIG. 9 shows a voltage timing diagram of driving signals of two LED packaging structures 1. The first driving signal, the second driving signal, and the third driving signal can respectively control the first pixel structure 104, the second pixel structure 105, and the third pixel structure 106 in a corresponding LED packaging structure 1. Specifically, when the first driving signal is at a high level, the first pixel structure 104 in the corresponding LED packaging structure 1 is lit; when the second driving signal is at a high level, the second pixel structure 105 in the corresponding LED packaging structure 1 is lit; and when the third driving signal is at a high level, the third pixel structure 106 in the corresponding LED packaging structure 1 is lit. Therefore, at a same time, types of the pixel structures lit in the two LED packaging structures 1 are different, so colors of light emitted by the two LED packaging structures 1 are also different at the same time, which can reduce a color separation phenomenon of the multi-color LED matrix.

In an embodiment, referring to FIGS. 4 and 9, manually setting the control instruction VC can cause at least one LED packaging structure 1 in the multi-color LED matrix to emit light of one color of a plurality of colors and at least one LED packaging structure 1 to emit light of another color of the plurality of colors, enabling the multi-color LED matrix to emit at least two colors of light, thereby avoiding the color separation phenomenon of the multi-color LED matrix. In this configuration, the control instruction VC is input into the active LED module through the data input pin DI, and the control instruction VC can be transmitted to the driver chip 102 through the data input pin DI, so that the driver chip 102 controls a lighting order of the LED packaging structure 1 according to the control instruction VC.

In another embodiment, referring to FIGS. 5 and 9, the driver chip 102 further includes a random signal module. Because the output signal of the random signal module is random, the lighting order of different types of pixel structures in each LED packaging structure 1 in the multi-color LED matrix is also random. Therefore, at a same time, a plurality of LED packaging structures 1 can emit light of one, two, or three colors. However, when the plurality of LED packaging structures 1 emit light of the same color, the multi-color LED matrix produces a color separation phenomenon; thus, adding the random signal module in the driver chip 102 can reduce the color separation phenomenon of the multi-color LED matrix.

This embodiment is a method embodiment adopting the above-mentioned structural embodiments. Therefore, for a detailed explanation of each feature in this embodiment, please refer to the relevant description of the same feature in the above structural embodiments, and details are not repeated here.

Although the present application is disclosed as above, it is not limited thereto. Any person skilled in the art can make various changes and modifications without departing from the spirit and scope of the present application. Therefore, the scope of protection of the present application should be defined by the scope of the claims.

What is claimed is:

1. An LED packaging structure, comprising:
an active LED module, the active LED module comprising a first multi-color light-emitting unit, a driver chip, and a plurality of driving signal output pin sets, wherein the driver chip is connected to the first multi-color light-emitting unit, the first multi-color light-emitting unit and the driver chip are located within a same package body, and the driving signal output pin sets are configured to output driving signals;
two active power supply pin sets, both of the two active power supply pin sets being coupled to the active LED module;
at least one first-type passive LED module, the first-type passive LED module comprising a second multi-color light-emitting unit and a driving signal input pin set, wherein the driving signal input pin set is connected to a corresponding one of the driving signal output pin sets, and the driver chip is configured to drive the first multi-color light-emitting unit and the second multi-color light-emitting unit to emit light of a same color at a same time, the color being one of a plurality of colors; and
at least two passive power supply pin sets, wherein every two of the passive power supply pin sets are coupled to one corresponding first-type passive LED module, and a number of the passive power supply pin sets is twice a number of the first-type passive LED modules; wherein the active power supply pin sets are connected to the passive power supply pin sets adjacent thereto, the remaining passive power supply pin sets are connected to the passive power supply pin sets adjacent thereto, and two connected passive power supply pin sets are respectively coupled to different first-type passive LED modules.

2. The LED packaging structure of claim 1, wherein both of the two active power supply pin sets are connected to the active LED module, and each two of the passive power supply pin sets are connected to a corresponding one of the first-type passive LED modules.

3. The LED packaging structure of claim 1, wherein the first multi-color light-emitting unit and the second multi-color light-emitting unit each comprise a first pixel structure, a second pixel structure, and a third pixel structure, wherein colors of light emitted by the first pixel structure, the second pixel structure, and the third pixel structure are different from one another;
the driver chip is respectively connected to the first pixel structure, the second pixel structure, and the third pixel structure in the first multi-color light-emitting unit;
each of the driving signal output pin sets comprises a first driving signal output pin, a second driving signal output pin, and a third driving signal output pin, and each of the driving signal input pin sets comprises a first driving signal input pin, a second driving signal input pin, and a third driving signal input pin; and
in one of the driving signal output pin sets and the driving signal input pin set corresponding thereto, the first driving signal output pin is connected to the first driving signal input pin, the second driving signal output pin is connected to the second driving signal input pin, and the third driving signal output pin is connected to the third driving signal input pin.

4. The LED packaging structure of claim 3, further comprising:
a plurality of second-type passive LED modules connected in series, wherein in a first one of the second-type passive LED modules and the active LED module, the first pixel structure of one is correspondingly connected to the first pixel structure of the other, the second pixel structure of one is correspondingly connected to the second pixel structure of the other, and the third pixel structure of one is correspondingly connected to the third pixel structure of the other; a last one of the second-type passive LED modules is connected to the two active power supply pin sets; and in any two adjacent ones of the second-type passive LED modules, the first pixel structure of one is correspondingly connected to the first pixel structure of the other, the second pixel structure of one is correspondingly connected to the second pixel structure of the other, and the third pixel structure of one is correspondingly connected to the third pixel structure of the other; and
a plurality of third-type passive LED module sets, each of the third-type passive LED module sets comprising a plurality of third-type passive LED modules connected in series, wherein a number of the third-type passive LED modules in each set is the same as a number of the second-type passive LED modules; in each of the third-type passive LED module sets, a first one of the third-type passive LED modules corresponds to a corresponding one of the first-type passive LED modules, and in the first one of the third-type passive LED modules and the first-type passive LED module corresponding thereto, the first pixel structure of one is correspondingly connected to the first pixel structure of the other, the second pixel structure of one is correspondingly connected to the second pixel structure of the other, and the third pixel structure of one is correspondingly connected to the third pixel structure of the other; a last one of the third-type passive LED modules is connected to two of the passive power supply pin sets; and in any two adjacent ones of the third-type passive LED modules, the first pixel structure of one is correspondingly connected to the first pixel structure of the other, the second pixel structure of one is correspondingly connected to the second pixel structure of the other, and the third pixel structure of one is correspondingly connected to the third pixel structure of the other.

5. The LED packaging structure of claim 3, wherein each of the active power supply pin sets comprises a first active power supply pin, a second active power supply pin, and a third active power supply pin, and each of the passive power supply pin sets comprises a first passive power supply pin, a second passive power supply pin, and a third passive power supply pin;
wherein the first active power supply pin and the first passive power supply pin are connected to a same power supply voltage to supply power to the first pixel structure; the second active power supply pin and the second passive power supply pin are connected to a same power supply voltage to supply power to the second pixel structure; and the third active power supply pin and the third passive power supply pin are connected to a same power supply voltage to supply power to the third pixel structure; and
the first active power supply pin, the second active power supply pin, and the third active power supply pin are connected to power supply voltages of different magnitudes.

6. The LED packaging structure of claim 3, wherein each of the active power supply pin sets comprises a first active power supply pin and a fourth active power supply pin, and each of the passive power supply pin sets comprises a first passive power supply pin and a fourth passive power supply pin;
wherein the first active power supply pin and the first passive power supply pin are connected to a same power supply voltage to supply power to the first pixel structure; the fourth active power supply pin and the fourth passive power supply pin are connected to a same power supply voltage to supply power to the second pixel structure and the third pixel structure; and
the first active power supply pin and the fourth active power supply pin are connected to power supply voltages of different magnitudes.

7. The LED packaging structure of claim 3, wherein the driver chip is configured to output a corresponding driving signal according to a control instruction; or, the driver chip comprises a random signal module, the random signal module being configured to control the driver chip to randomly output a driving signal;
wherein the driving signal is configured to control a lighting order of the LED packaging structure within a frame of time, the driving signal comprises a first driving signal, a second driving signal, and a third driving signal, the first driving signal, the second driving signal, and the third driving signal being respectively used to drive the first pixel structure, the second pixel structure, and the third pixel structure in the first multi-color light-emitting unit and the second multi-color light-emitting unit; each of the driving signal output pin sets comprise the first driving signal output pin, the second driving signal output pin, and the third driving signal output pin, the first driving signal output pin, the second driving signal output pin, and the third driving signal output pin are respectively used to output the first driving signal, the second driving signal, and the third driving signal, and the driving signal is connected to the first pixel structure, the second pixel structure, and the third pixel structure in the first multi-color light-emitting unit.

8. A multi-color LED matrix, comprising:
a lamp board; and
a plurality of the LED packaging structures of claim 1, the LED packaging structures being distributed in an array on the lamp board;
wherein a plurality of the active LED modules are connected in series through a data input pin and a data output pin, wherein in any two adjacent ones of the active LED modules, the data output pin of one is connected to the data input pin of the other.

9. A control method for a multi-color LED matrix, comprising controlling the multi-color LED matrix of claim 8.

10. The control method for a multi-color LED matrix of claim 9, wherein a number of the LED packaging structures is at least two, and the control method comprises: at a same time, light emitted by at least one of the LED packaging structures is one color of the plurality of colors, and light emitted by at least one of the LED packaging structures is another color of the plurality of colors.
